(19) United States
(12) Patent Application Publication
(10) Pub. No.: US 2025/0087988 A1
(43) Pub. Date: Mar. 13, 2025

(54) DEVICE HAVING REDUNDANT POWER SUPPLY LINES

(71) Applicant: Murrelektronik GmbH, Oppenweiler (DE)

(72) Inventors: Kai Fortwingel, Abstatt (DE); Ingo Wolff, Oehringen (DE)

(21) Appl. No.: 18/827,386

(22) Filed: Sep. 6, 2024

(30) Foreign Application Priority Data
Sep. 7, 2023 (EP) 23196097.2

(51) Int. Cl. H02H 3/05; G01R 31/52; H02H 1/00; H02H 3/087; H02H 3/28

(52) U.S. Cl. CPC H02H 3/05; G01R 31/52; H02H 1/0023; H02H 3/087; H02H 3/28

(57) ABSTRACT

A device has an electric power supply line between an electrical load and a DC voltage source with a positive pole and a negative pole. The supply line delivers the requisite electrical energy for the operation of the load. The electric power supply line includes at least four adjacently routed, identically configured and insulated individual conductors of equal length, wherein at least two individual conductors connect the positive pole to the load, and at least two individual conductors connect the negative pole to the load. Each of the individual conductors forms an independent electrical connection between the DC voltage source and the electrical load.

### CROSS-REFERENCE TO RELATED APPLICATIONS

This application claims priority of European patent application no. 23196097.2, filed Sep. 7, 2023, the entire content of which is incorporated herein by reference.

### TECHNICAL FIELD

The disclosure relates to a device having an electric power supply line between an electrical load and a DC voltage source with a positive pole and a negative pole. The supply line delivers the requisite electrical energy for the operation of the load.

### BACKGROUND

In an automated production installation, unforeseeable repairs and outages of systems and machines generate costs and time delays. One cause of an outage can be failed electrical conductors. In an automated production installation, electrical conductors are not only subject to electrical loads, but also to mechanical loads. For example, electrical conductors are present in a cable chain or on components of a robot which execute mechanical movements. In particular, malfunctions on the supply lines of sensors, actuators or I/O systems (input/output systems) can result in substantial downtimes, until such time as the defective supply lines can be identified and replaced.

A particular issue in automated production installations is the generation of an arc on a failed electric power supply line. Voltages and currents applied can cause an arc of this type to be sustained, which can additionally result in fire damage.

### SUMMARY

An object of the disclosure is the configuration of an electric power supply line in an automated production installation such that hazards associated with electrical defects on the supply line, and the resulting consequences thereof, such as downtimes of the production installation and the risk of fire associated with arcing, are minimized.

According to the disclosure, it is provided that the electric power supply line includes at least four adjacently routed, essentially identically configured and insulated individual conductors of approximately equal length. At least two individual conductors connect the positive pole of the voltage source to the load, and at least two further individual conductors connect the negative pole of the voltage source to the load. The layout is executed such that each of the individual conductors forms an independent electrical connection between the DC voltage source and the electrical load.

Within the meaning of the disclosure, a load can include a single device, or an assembly of mutually interconnected devices. An interconnected arrangement of DC voltage sources, for example, formed by the series connection of individual batteries, is also to be understood as a DC voltage source within the meaning of the disclosure.

The redundant energy supply to the electrical load ensures that, in the event of the failure of one individual conductor, the other individual conductor will continue to maintain a stable electrical connection between the DC voltage source and the electrical load. To this end, preferably, each of the individual conductors is rated for the nominal current of the electrical load.

In a production installation or a similar system, the at least four individual conductors are combined in a common connecting cable. This permits a simple fitting and removal of the connecting cable. The cable can additionally incorporate a FE (Functional Earth) conductor.

It is advantageously provided that the individual conductors assume an equal electrical resistance. In particular, the individual conductors are of an equal cross-section and are preferably formed of an identical material, preferably of an identical metal alloy. It is provided that the sum of the current-carrying capacities of all the individual conductors is rated as at least equivalent to the nominal current of the connected load.

In a first variant of dimensioning, the sum of the current-carrying capacities of the individual conductors is rated for at least the nominal current of the load. The current-carrying capacity of an individual conductor can lie below the nominal current of the load. In this arrangement, in the event of the detection of an electrical fault in an individual conductor, it is necessary for the supply to be disconnected. In this variant, a fault can be detected in the form of a line failure. Disadvantageous consequences, such as, for example, fires associated with arcing, can be prevented.

In a second variant of dimensioning, parallel individual conductors are respectively rated for at least the nominal current of the load. This produces “1+1 redundancy”. In the event of the failure of an individual conductor, the installation can continue to operate. The defective conductor can be replaced at a subsequent service interval.

In a further variant of dimensioning, more than two individual conductors are parallel-connected. This is described as a n+1 variant of dimensioning. The individual conductors are rated such that the current-carrying capacity is divided between the individual conductors. It is provided that the number of individual conductors, the systematic failure of which is not tolerated, corresponds to the rated capacity of the load. If, for example, in a system having three parallel individual conductors, the systematic failure of one conductor is tolerated, each of the remaining individual conductors should be capable of assuming a current-carrying capacity which is equivalent to 50% of the rated capacity of the load. This type of redundancy is particularly material-saving.

The DC voltage source for supplying the electrical load preferably has a supply voltage between 24 V and 120 V DC.

For fault detection, according to a further embodiment of the disclosure, it is provided that at least one monitoring device is arranged between at least two individual conductors. The monitoring device can thus be arranged between the individual conductors of the conduction path which connects the positive pole of the DC voltage source to the load and/or between the individual conductors of the conduction path which connects the negative pole of the DC voltage source to the load.

In a simple configuration of the monitoring device, the latter captures currents flowing in the individual conductors and evaluates the magnitude thereof. If these currents are evaluated as equal, in consideration of applicable tolerances, the individual conductors are in order; the occurrence of a significant current difference indicates the presence of a fault. The monitoring device is configured, in response to the occurrence of a current difference or any other fault, to generate a signal output and/or to trip a cut-off device. For the capture of currents flowing in the individual conductors, a current sensor is respectively provided in each of the individual conductors.

In a further configuration of the monitoring device, it is provided that the latter captures and evaluates electromagnetic fields associated with currents flowing in the individual conductors. To this end, the magnitude of electromagnetic fields captured on two individual conductors, in each case, are mutually compared in order to permit, in the event of a field difference, the generation of a signal output and/or the tripping of a cut-off device. The monitoring device can thus evaluate the current difference in the individual conductors by reference to the magnetic field. To this end, the individual conductors are installed such that, at an equal current flux, the electromagnetic field at the measuring point is cancelled out. If the currents are different, an electromagnetic field difference is generated, which is evaluated.

It can be advantageous for line sections of the individual conductors to be configured in the form of a coil at the measuring point. The resulting field generated by the differential current is evaluated by a magnetic field sensor, preferably a Hall effect sensor. Alternatively, the magnetic field can be employed for the actuation of a mechanical component. A mechanical component of this type can be a reed contact or a corresponding trip mechanism.

In a further embodiment of the disclosure, it is provided that the monitoring device captures and evaluates the temperatures at a respectively preselected connection point of the individual conductors. The monitoring device mutually compares temperatures which are captured at the preselected connection points, and is configured, in the event of the occurrence of a temperature difference, to generate a signal output and/or to trip a cut-off device. In an advantageous manner, connection points of the individual conductors which are assigned to a conduction path are mutually compared. The connection point of the individual conductors can be, for example, a soldered connection, a terminal connection, a plug-in connection, or a connection of the individual conductor to a circuit board. Connection points, the temperatures of which are mutually compared, are preferably arranged at the same end of the individual conductors.

In a further embodiment of the disclosure, it is provided that the monitoring device is arranged on a circuit board which is connected to the DC voltage source. The monitoring device and/or the circuit board is provided with a socket, into which the plug of a connecting cable can be plugged, which forms the connecting line to the load.

### BRIEF DESCRIPTION OF DRAWINGS

The invention will now be described with reference to the drawings wherein:

FIG. 1 shows a schematic representation of the device for connecting an electrical load to a DC voltage source via two conduction paths, via a single electric power supply line;

FIG. 2 shows a schematic representation corresponding to FIG. 1, with a supply line configured in the form of a cable;

FIG. 3 shows a schematic representation according to FIG. 1, with a monitoring device for capturing and evaluating currents flowing in the individual conductors of a conduction path;

FIG. 4 shows a schematic representation of a monitoring device for capturing and evaluating the electromagnetic fields of two individual conductors in a conduction path of the connecting line;

FIG. 5 shows a schematic representation according to FIG. 1, with a monitoring device for capturing and evaluating temperatures at selected connection points in a conduction path of the supply line; and,

FIG. 6 shows a schematic representation of an electronic circuit for capturing and evaluating temperatures at two connection points arranged at one end of the conduction path of the supply line.

### DETAILED DESCRIPTION

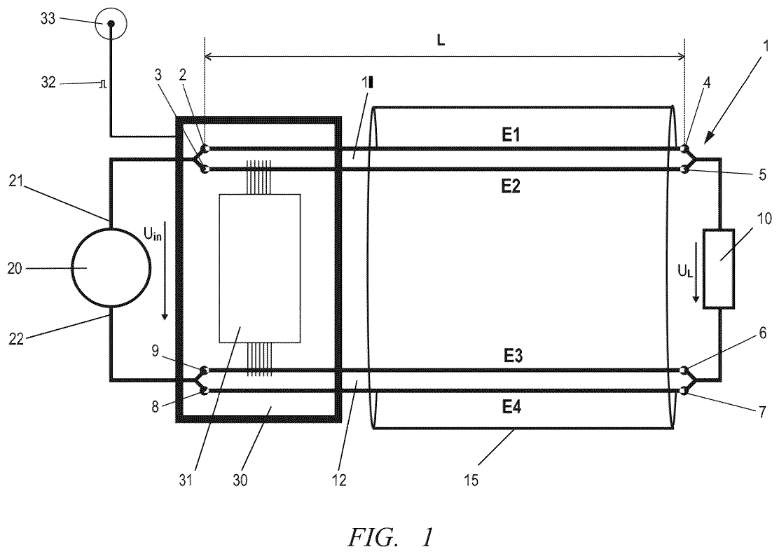

FIG. 1 shows a schematic representation of the device, via which an electrical connection is established between a DC voltage source 20 and an electrical load 10. The electrical connection is formed by at least four individual conductors E1, E2, E3, E4, which are preferably routed next to one another, and are configured in the form of insulated individual conductors E1, E2, E3, E4. In particular, the individual conductors E1, E2, E3, E4 are combined in a common connecting cable 15. Appropriately, the individual conductors E1, E2, E3, E4 are identically configured, and preferably assume approximately identical and, in particular, identical lengths L. As shown, at least two individual conductors E1 and E2 connect the positive pole 21 of the DC voltage source 20 to the electrical load 10. At least a further two individual conductors E3 and E4 connect the negative pole 22 of the DC voltage source 20 to the load 10. The DC voltage source 20 preferably assumes a supply voltage between 24 and 120 V DC.

The layout is configured such that each of the individual conductors E1, E2, E3 and E4 forms an independent electrical connection between the DC voltage source 20 and the electrical load 10. Each of the individual conductors E1, E2, E3 and E4, in particular, is rated for the permissible nominal current of the connected electrical load 10. The individual conductors E1 and E2 which connect the positive pole 21 of the DC voltage source 20 to the electrical load 10 form a first electrical conduction path 11. The individual conductors E3 and E4 which connect the negative pole 22 of the DC voltage source 20 to the electrical load 10 form a second electrical conduction path 12.

The positive pole 21 of the DC voltage source 20 is respectively connected to one of the individual conductors E1 and E2 via two connection points 2 and 3. Correspondingly, the individual conductors E1 and E2, at the other end of the individual conductors E1 and E2, are electrically connected to the electrical load 10, on the side of the electrical load 10, via the connection points 4 and 5. The connection points 2 and 3 are arranged at one end of the conduction path 11. The connection points 4 and 5 are arranged at the other end of the conduction path 11.

The individual conductors E3 and E4, on the side of the electrical load, are connected thereto via the connection points 6 and 7. On the side of the DC voltage source 20, the individual conductors E3 and E4 are connected to the negative pole 22 of the DC voltage source 20 via the connection points 8 and 9. The connection points 6 and 7 are arranged at one end of the conduction path 12. The connection points 8 and 9 are arranged at the other end of the conduction path 12.

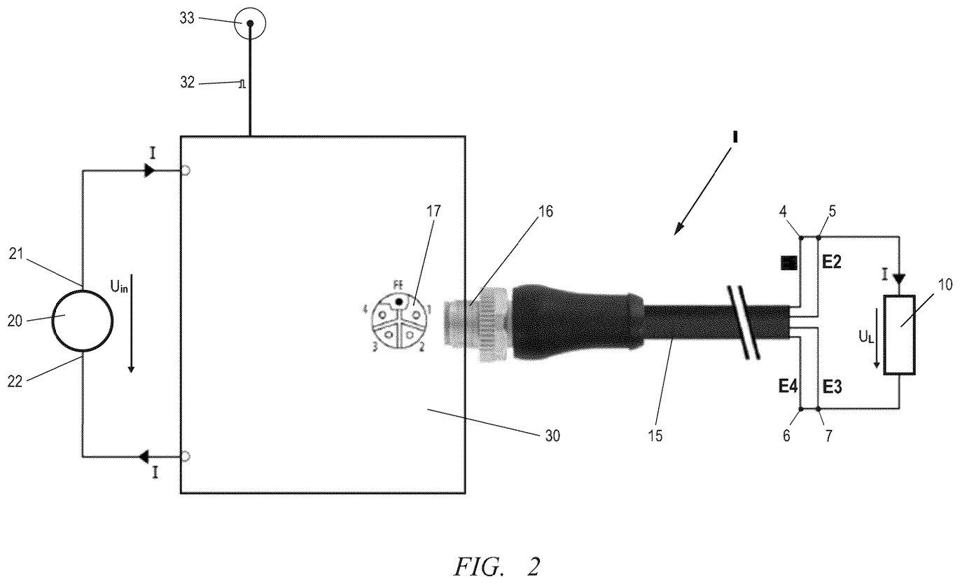

In FIG. 2, the connecting cable 15 to the electrical load 10 is physically represented. The connecting cable 15, via a plug 16, is plugged into a socket 17 which is provided on the monitoring device 30 and/or on a circuit board which carries a monitoring electronic circuit 31.

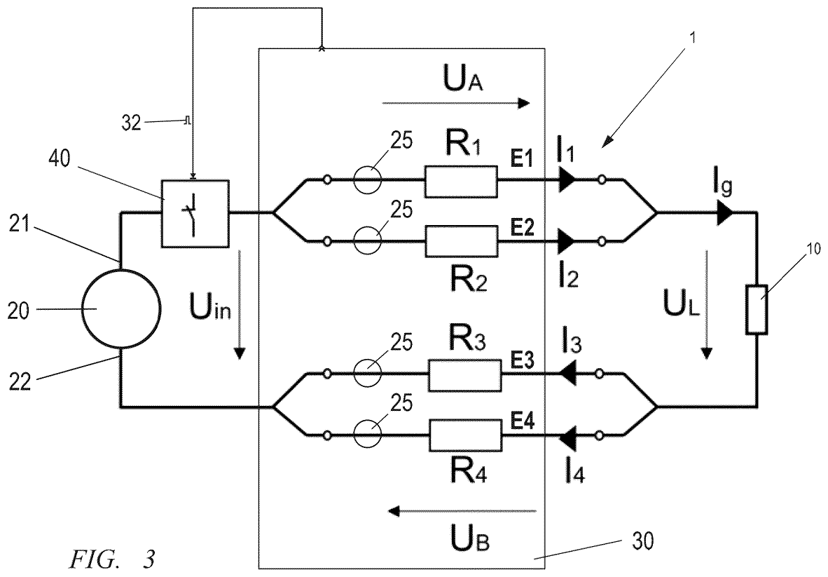

For the detection of electrical faults on the individual conductors E1, E2, E3 and E4, a monitoring device 30 is provided, which includes a monitoring electronic circuit 31. In the event of the occurrence of faults, the monitoring device 30 is configured to output an electrical signal 32. The electrical signal 32 can control an optical display 33 or, as exemplarily represented in FIG. 3, can activate a cut-off device 40. The function of the monitoring device 30, in various embodiments, is described hereinafter.

The individual conductors E1, E2, E3 and E4 are preferably configured such that they assume an equal electrical resistance. In the physical configuration of the individual conductors E1, E2, E3 and E4, the latter are preferably of an equal cross-section. The individual conductors E1, E2, E3 and E4 are appropriately formed of an identical material, or of an identical alloy.

The monitoring device 30 represented is provided such that the monitoring electronic circuit 31 is respectively arranged between two individual conductors E1 and E2 of the conduction path 11 and/or between two individual conductors E3 and E4 of the conduction path 12.

In a first embodiment of the monitoring device 30 shown in FIG. 3, current sensors 25 are arranged in the individual conductors E1, E2, E3 and E4, which capture the influx currents I₁ and I₂ to the individual conductors E1 and E2 and the outflow currents I₃ and I₄ in the individual conductors E3 and E4. On the grounds of the identical configuration of the individual conductors, the resistances R₁ and R₂ of the individual conductors E1 and E2 are equal. A voltage drop UA occurs across the resistors R₁ and R₂. The resistances R₃ and R₄ are also equal. The voltage drop across the latter is U_{B}. The monitoring device 30 is configured to compare the currents I₁, I₂ and/or I₃, I₄ with one another. In the event of the occurrence, for example, of a conductor failure on the individual conductor E1, the currents I₁ and I₂ vary. In the event of a current difference, the monitoring device 30—as schematically represented in FIG. 1—outputs a signal 32 and/or trips a cut-off device 40, in order to interrupt the circuit.

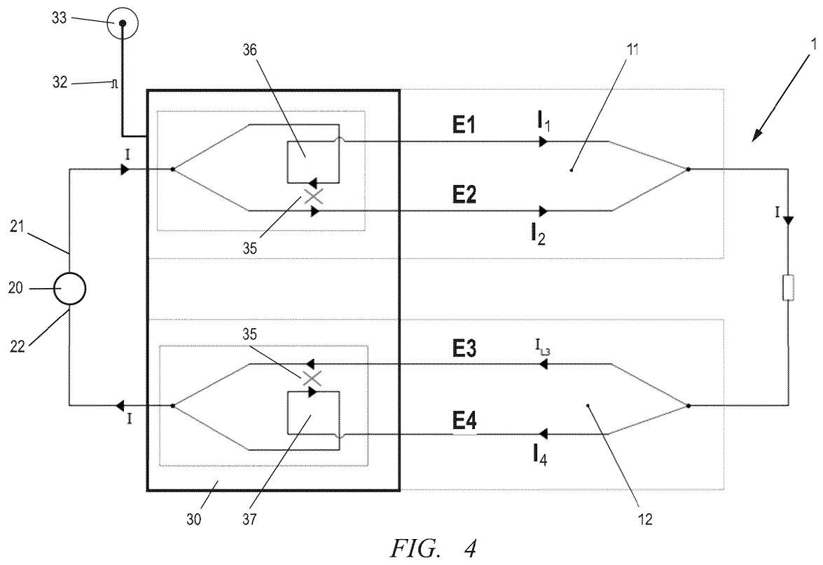

In the embodiment according to FIG. 4, a monitoring device 30 is represented which captures and evaluates the resulting electromagnetic differential fields associated with the currents I₁ and I₂ or I₃ and I₄ flowing in the individual conductors E1 and E2 or E3 and E4. In a simple configuration, it is provided that a magnetic field sensor, in particular a Hall effect sensor 35, is employed. As represented in the conduction path 11, the individual conductor E1 is configured with a loop 36, such that the current I₁ flowing in the individual conductor E1 is mutually opposed to the current I₂ flowing in the individual conductor E2, at the Hall effect sensor 35. If the currents I₁ and I₂ are equal, the Hall effect sensor 35 outputs no signal. If the currents I₁ and I₂ are of different magnitudes, a fault is present. The Hall effect sensor 35 outputs a signal to the monitoring device 30. The latter generates an output signal 32 which indicates the fault and/or actuates a cut-off device 40.

Currents I₃ and I₄ flowing in the individual conductors E3 and E4 of the conduction path 12 are also monitored by a Hall effect sensor 35. The individual conductor E4 is configured with a loop 37, such that currents at the Hall effect sensor 35 are in mutual opposition.

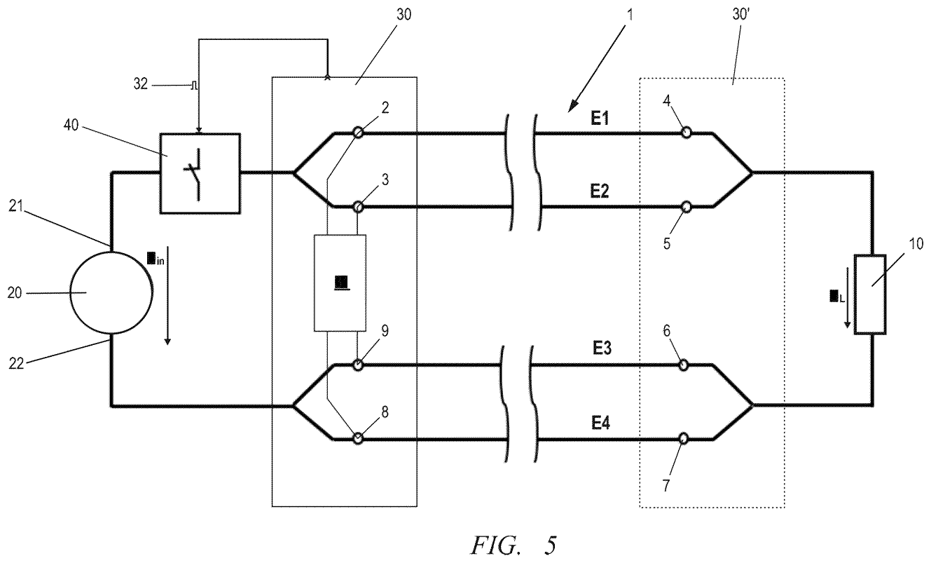

In the embodiment according to FIG. 5, a monitoring device 30 or 30′ is represented, which captures and evaluates temperatures at respectively preselected connection points 2, 3, 4, 5, 6, 7, 8 or 9 of the individual conductors E1, E2, E3 or E4. On the monitoring device 30 it is shown how, via a monitoring electronic circuit 31, temperatures at the connection points 2 and 3 at one end of the conduction path 11 and/or temperatures at the connection points 8 and 9 at the other end of the conduction path 12 are captured and mutually compared. In the event of the occurrence of a temperature difference, a signal output is generated and/or a cut-off device 40 is tripped. A connection point 2 to 9 of the individual conductors E1, E2, E3 or E4 can be a soldered connection, a terminal connection, a plug-in connection, or a connection to a circuit board of the monitoring electronic circuit 31.

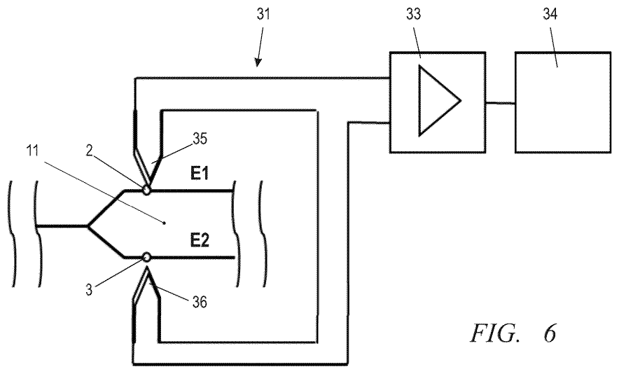

FIG. 6 shows a schematic representation of a monitoring electronic circuit 31 which captures and evaluates temperatures at the connection points 2 and 3 which are located at one end of the conduction path 11. A first temperature sensor 35 which is arranged on the connection point 2 is preferably connected in series with a temperature sensor 36 which is arranged on the connection point 3. Via a differential amplifier 33, the differential signal from the temperature sensors 35 and 36 is amplified and is evaluated in a microprocessor 34.

It is understood that the foregoing description is that of the preferred embodiments of the invention and that various changes and modifications may be made thereto without departing from the spirit and scope of the invention as defined in the appended claims.

1. A device interposed between an electrical load and a DC voltage source having a positive pole and a negative pole, said device comprising:
an electric supply line between said electrical load and said DC voltage source for delivering a requisite electrical energy for operating said load;
said electric supply line including four individual conductors;
said four individual conductors being adjacently routed, identically configured, individually insulated and being of equal length;
a first two individual conductors of said four individual conductors connecting said positive pole to said load and a second two individual conductors of said four individual conductors connecting said negative pole to said load;
each of said four individual conductors forming an independent electrical connection between said DC voltage source and said electrical load;
a monitor arranged between said first two individual conductors and said second two individual conductors; and,
wherein one of the following applies:
i) said monitor is configured to execute a comparison of respective currents flowing in said individual conductors; and, to do at least one of the following in response to a current difference in said individual conductors: a) generate a signal output; and, b) trigger a cutoff device; or,
ii) said monitor is configured to capture electromagnetic fields associated with currents flowing in said individual conductors and to execute a mutual comparison of electromagnetic fields associated with currents flowing in two respective individual conductors and, in response to a field difference to do at least one of: a) generate a signal output; and, b) to trigger a cut-off device; or,
iii) said monitor is configured to capture the temperature at a respectively preselected connection point of said individual conductors and to execute a mutual comparison of temperatures at the preselected connection points of the individual conductors and, in response to a temperature difference, to do at least one of: a) generate a signal output; and, b) trigger a cut-off device.

2. The device of claim 1, wherein said four individual conductors are combined in a common connecting cable.

3. The device of claim 1, wherein said individual conductors exhibit at least one of the following properties: a) assume an equal electrical resistance; b) are of an equal cross-section; and, c) are formed of an identical material; and, d) are formed of an identical alloy.

4. The device of claim 1, wherein all the individual conductors are rated for at least the nominal current of said load connected thereto.

5. The device of claim 1, wherein said DC voltage source has a supply voltage between 24 V and 120 V.

6. The device of claim 1, wherein said monitor is arranged between said first two individual conductors defining a first conduction path, which connects the positive pole of the DC voltage source to said load, and between said second individual conductors defining a second conduction path which connects said negative pole of the DC voltage source to said load.

7. The device of claim 1, wherein: for capturing currents flowing in corresponding ones of said individual conductors, a plurality of current sensors are provided in corresponding ones of said individual conductors.

8. The device of claim 1, wherein said individual conductors define respective connector points which are each a soldered connection, a terminal connection, a plug-in connection or a connection to a circuit board.

9. The device of claim 1, wherein said monitor includes a socket for connecting said electric supply line which is routed to said load.
